(19) United States
(12) Patent Application Publication
(10) Pub. No.: US 2026/0237613 A1
(43) Pub. Date: Aug. 13, 2026

(54) JOINT BODY AND MEMBER FOR SEMICONDUCTOR MANUFACTURING APPARATUS

(71) Applicant: NGK INSULATORS, LTD., Nagoya-shi (JP)

(72) Inventors: Atsushi ISHIKAWA, Handa-city (JP); Hiroshi TAKEBAYASHI, Handa-city (JP); Jyunya WAKI, Handa-city (JP)

(21) Appl. No.: 19/632,950

(22) Filed: Mar. 30, 2026

Related U.S. Application Data
(63) Continuation of application No. PCT/JP2025/036465, filed on Oct. 16, 2025.

(30) Foreign Application Priority Data
Dec. 26, 2024 (JP) 2024-230939

(51) Int. Cl. H01J 37/32; H10P 72/72

(52) U.S. Cl. CPC H01J 37/32724; H01J 37/32467; H01J 37/32568; H10P 72/722; H01J 2237/2007

(57) ABSTRACT

A joint body used by being fastened to a base member, the joint body includes a ceramic plate that has a wafer placement surface on its upper surface, and an electrode embedded therein; a back-side plate joined to a back side of the ceramic plate; a disposition space in which a joint-body-side fastening member is disposed at a time of fastening, the disposition space being provided in the back-side plate and having a through hole at a bottom; and a movement lane used for insertion and removal of the joint-body-side fastening member, the movement lane starting from a port open in a lower surface or a side surface of the back-side plate and reaching the disposition space which is different from the port in position in a plan view.

### CROSS-REFERENCE TO RELATED APPLICATION

This application is a continuation application of PCT/JP2025/036465, filed on October 16, 2025, which claims the benefit of priority of Japanese Patent Application No. 2024-230939 filed on December 26, 2024,the entire contents of which are incorporated herein by reference.

### BACKGROUND OF THE INVENTION

### 1. Field of the Invention

The present invention relates to a joint body and a member for semiconductor manufacturing apparatus.

### 2. Description of the Related Art

As a member for semiconductor manufacturing apparatus, a wafer placement table including a joint body is conventionally known, the joint body joining a ceramic substrate, and a first cooling substrate having a lower surface with an open threaded hole (see, for example, PTL 1). In the wafer placement table, the joint body joining the ceramic substrate and the first cooling substrate is fastened to a second cooling substrate by screwing a screw member into a threaded hole open in the lower surface of the first cooling substrate, the screw member being inserted into a through hole of the second cooling substrate. In addition, a wafer placement table including an electrostatic chuck assembly is known, the electrostatic chuck assembly being a joint body joining a ceramic plate, and a cooling plate storing a fixing member having a female thread portion in an internal space (see, for example, PTL 2). In the electrostatic chuck assembly, the bottom of the cooling plate is provided with a hole to expose a female thread portion, and a chamber fixing bolt is inserted through the hole, and screwed to the female thread portion serving as a fixing member to be fixed to the chamber.

### Citation List

### Patent Literature

PTL 1: WO 2024/004040 A1

PTL2: WO 2024/069816 A1

### SUMMARY OF THE INVENTION

However, in PTL 1, if a failure occurs in the threaded hole of the first cooling substrate, due to a disabled fastening, the joint body joining the ceramic substrate and the first cooling substrate may become unusable. In PTL 2, the fixing member is provided with multiple sets of female thread portions, and when the fixing member is rotated about the central axis of the cooling plate, another set of female thread portion is to be exposed to the bottom of the cooling plate, thus if a failure occurs in a female thread portion, the female thread portion in another set is exposed to enable fastening. However, if a failure occurs in all sets of female thread portions of the fixing member, due to a disabled fastening, the electrostatic chuck assembly, which is the joint body joining the ceramic plate and the cooling plate, may become unusable.

The present invention has been devised to solve such a problem, and it is a main object to prevent the joint body from becoming unusable due to a failure of a fastening member.

[1] A joint body of the present invention is used by being fastened to a base member, the joint body including: a ceramic plate that has a wafer placement surface on its upper surface, and an electrode embedded therein; a back-side plate joined to a back side of the ceramic plate; a disposition space in which a joint-body-side fastening member is disposed at a time of fastening, the disposition space being provided in the back-side plate and having a through hole at a bottom; and a movement lane used for insertion and removal of the joint-body-side fastening member, the movement lane starting from a port open in a lower surface or a side surface of the back-side plate and reaching the disposition space which is different from the port in position in a plan view.

In addition to the disposition space in which the joint-body-side fastening member is disposed, the joint body includes the movement lane used for insertion and removal of the joint-body-side fastening member. Thus, the joint-body-side fastening member can be replaced, and even if a defect occurs in the joint-body-side fastening member, replacing it with a new joint-body-side fastening member enables fastening again, and the joint body is prevented from becoming unusable due to a defect of the joint-body-side fastening member.

Note that in the present specification, the present invention will be described using terms such as upper and lower, right and left, front and rear; however, the upper and lower, right and left, front and rear only indicate a relative positional relationship. Thus, when the direction of a wafer placement table is changed, the upper and lower may be replaced by the right and left, or the right and left may be replaced by the upper and lower, and such case is also included in the technical scope of the present invention.

[2] In the above-described joint body (the joint body according to [1]), the bottom of the movement lane may be provided with a vertically penetrating slit along the movement lane. The joint-body-side fastening member can be easily replaced by inserting a jig or the like through the slit, and using the jig to move the joint-body-side fastening member within the movement lane.

[3] In the above-described joint body (the joint body according to [1] or [2]), the joint-body-side fastening member may be a nut, and the slit may have a width which allows insertion of a shaft of a bolt to be screwed in the joint-body-side fastening member, or the joint-body-side fastening member may be a bolt, and the slit may have a width which allows insertion of the shaft of the bolt of the joint-body-side fastening member. In this manner, when the joint-body-side fastening member is a nut, the joint-body-side fastening member can be replaced without specifically preparing a jig but using a bolt or the like used to fasten the base member. Alternatively, when the joint-body-side fastening member is a bolt, the joint-body-side fastening member can be replaced by gripping the shaft of the bolt.

[4] In the above-described joint body (the joint body according to any one of [1] to [3]), the sidewall of the disposition space may regulate the rotation of the joint-body-side fastening member about an axis. In this manner, fastening and removal of fastening with a rotation, such as screwing can be easily performed without performing a process such as rotation stop of the joint-body-side fastening member.

[5] In the above-described joint body (the joint body according to any one of [1] to [4]), the movement lane may start from one port and reach a plurality of disposition spaces each of which is the disposition space. In this manner, a plurality of joint-body-side fastening members can be inserted and removed from one port, thus each joint-body-side fastening member can be easily replaced.

[6] In the above-described joint body (the joint body according to any one of [1] to [5]), the back-side plate may be made of ceramic, and directly joined to the back side of the ceramic plate by joining. The back-side plate made of ceramic and the ceramic plate have a small difference in the coefficient of thermal expansion, thus warpage and delamination therebetween due to the difference in the coefficient of thermal expansion are unlikely to occur in the joint body, and the plates can be joined by direct joining. The direct joining is preferable due to high heat resistance of the joint part. The direct joining is often performed at a high temperature higher than or equal to the melting point of the ceramic, and the direct joining with the joint-body-side fastening member embedded in the back-side plate may be practically impossible in consideration of alteration of quality of the joint-body-side fastening member. Thus, it is highly significant to adopt the present invention which allows the joint-body-side fastening member to be inserted into the back-side plate after joining.

[7] In the above-described joint body (the joint body according to any one of [1] to [5]), the back-side plate may be made of a composite material of metal and ceramic, made of ceramic, or made of low thermal expansion metal, and may be joined to the back side of the ceramic plate by metal joining. The back-side plate made of a composite material of metal and ceramic or made of low thermal expansion metal, and the ceramic plate have a relatively small difference in the coefficient of thermal expansion, and the back-side plate made of ceramic and the ceramic plate have a smaller difference in the coefficient of thermal expansion, thus warpage and delamination therebetween due to the difference in the coefficient of thermal expansion are unlikely to occur in the joint body, and the plates can be joined by metal joining. The metal joining is also suitable for joining dissimilar materials, and provides high heat resistance, thus is preferable. The metal joining is often performed at a high temperature which is higher than or equal to the melting point of metal but not so high as in the direct joining. Thus, as in the direct joining, it is highly significant to adopt the present invention which allows the joint-body-side fastening member to be inserted into the back-side plate after joining.

[8] A member for semiconductor manufacturing apparatus of the present invention includes the above-described joint body (the joint body according to any one of [1] to [7]), and the member may include the base member; the joint-body-side fastening member; and a base-side fastening member that is used in combination with the joint-body-side fastening member.

The member for semiconductor manufacturing apparatus includes the above-described joint body, thus the joint body is prevented from becoming unusable due to a failure of the joint-body-side fastening member.

[9] In the above-described member for semiconductor manufacturing apparatus (the member for semiconductor manufacturing apparatus according to [8]), a gas may be filled in the space between a back side of the joint body and an upper surface of the base member. In this manner, heat transfer between the joint body and the base member can be adjusted by the gas.

[10] In the above-described member for semiconductor manufacturing apparatus (the member for semiconductor manufacturing apparatus according to [8] or [9]), a heat insulation member may be disposed in a periphery of at least one of the joint-body-side fastening member or the base-side fastening member. In this manner, heat transfer through the joint-body-side fastening member or the base body-side fastening member (hereinafter collectively referred to as the fastening member) between the joint body and the base member is reduced, thus occurrence of an extreme temperature difference is reduced between the portion immediately above or its peripheral area of the fastening member and other areas of the wafer placement surface.

### BRIEF DESCRIPTION OF THE DRAWINGS

FIG. 1 is a vertical sectional view of a wafer placement table 10 installed in a chamber 94.

FIG. 2 is a plan view of the wafer placement table 10.

FIG. 3 is a plan view with a ceramic plate 21 removed from FIG. 2.

FIGS. 4A to 4F are manufacturing process diagrams (manufacturing processes of a joint body 20) of the wafer placement table 10.

FIGS. 5A to 5D are manufacturing process diagrams (manufacturing processes of a nut 40) of the wafer placement table 10.

FIGS. 6A to 6C are manufacturing process diagrams (assembly processes of the wafer placement table 10) of the wafer placement table 10.

FIGS. 7A to 7C are explanatory diagrams illustrating another example of a movement lane 26.

FIGS. 8A to 8C are explanatory diagrams illustrating another example of the movement lane 26.

FIG. 9 is a partially enlarged view in FIG. 8A as seen in arrow A.

FIG. 10 is a vertical sectional view of a wafer placement table 110 installed in the chamber 94.

### DETAILED DESCRIPTION OF THE INVENTION

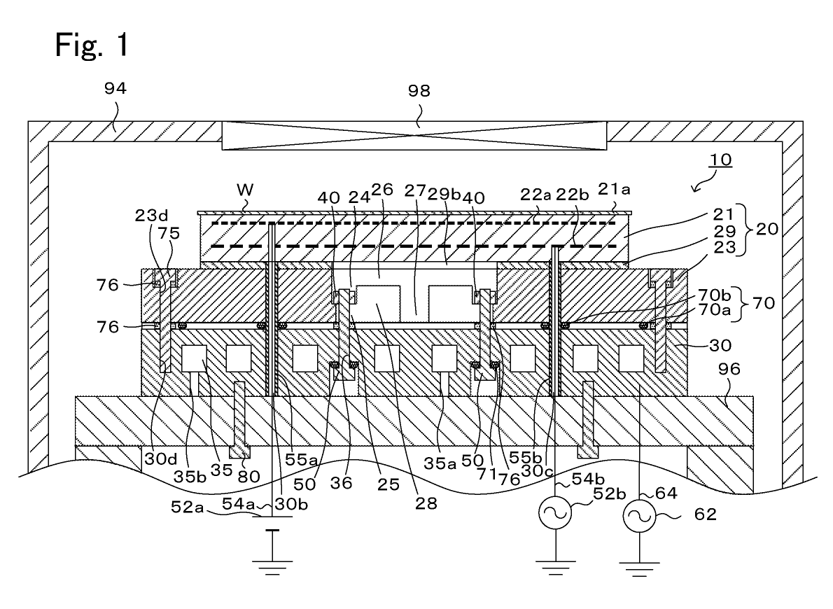

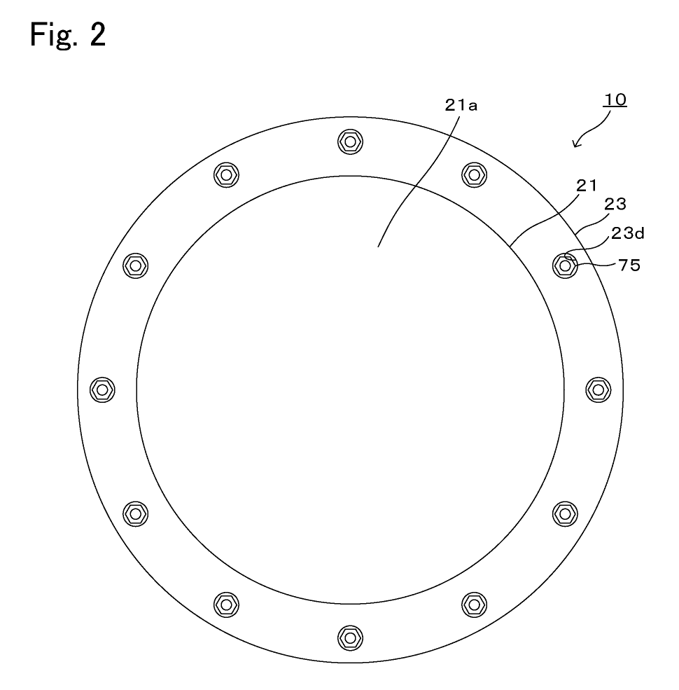

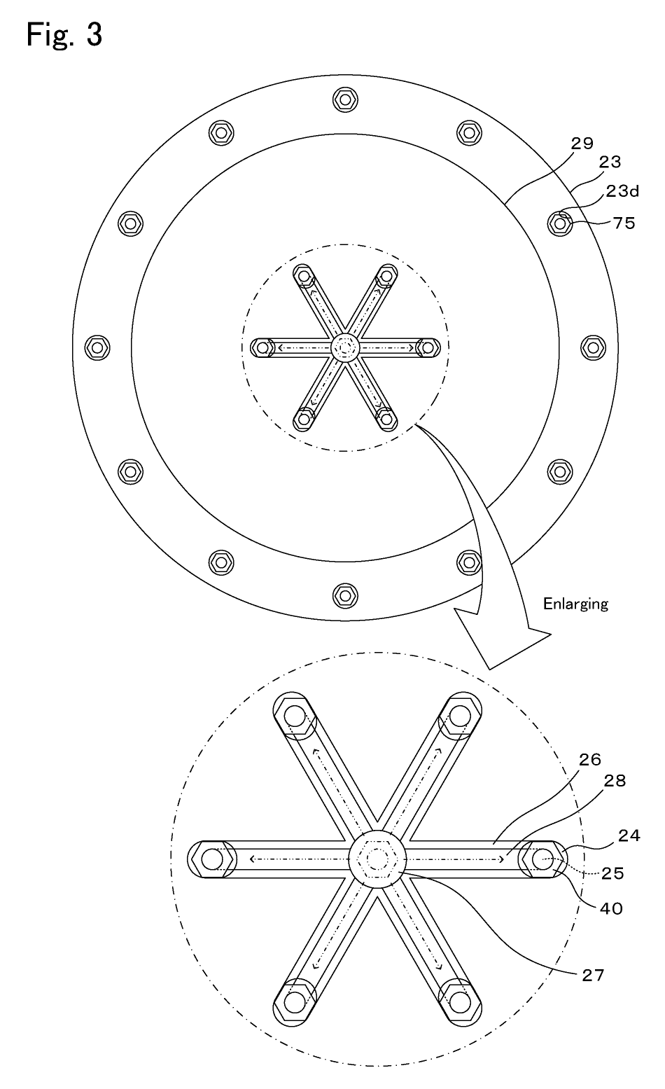

As a preferred embodiment of the semiconductor manufacturing apparatus of the present invention, a wafer placement table 10 used as an electrostatic chuck heater will be described below with reference to the drawings. FIG. 1 is a vertical sectional view (sectional view cut along a plane including the central axis of the wafer placement table 10) of the wafer placement table 10 installed in a chamber 94, FIG. 2 is a plan view of the wafer placement table 10, and FIG. 3 is a plan view with a ceramic plate 21 removed from FIG. 2. In the present specification, "-" showing a numerical range is used to mean that the range includes the numerical values preceding and subsequent to "-" as the lower limit value and the upper limit value.

The wafer placement table 10 is used to perform CVD and etching by utilizing plasma for a wafer W, and is fixed to an installation plate 96 provided inside the chamber 94 for semiconductor process. The wafer placement table 10 includes: a joint body 20 in which a ceramic plate 21 and a back-side plate 23 are joined; a base member 30; a nut 40 as a joint-body-side fastening member; and a bolt 50 as a base-side fastening member.

The joint body 20 includes the ceramic plate 21, the back-side plate 23, a disposition space 24, and a movement lane 26. The ceramic plate 21 and the back-side plate 23 are joined by a metal joint layer 29.

The ceramic plate 21 is e.g., a disk-shaped member with a diameter of approximately 300 mm, and includes a circular wafer placement surface 21a on its upper surface. The wafer W is placed on the wafer placement surface 21a. The ceramic plate 21 is made of a ceramic material represented by aluminum nitride or alumina. The ceramic plate 21 includes, as an inner electrode, a built-in wafer attraction electrode 22a on the side closer to the wafer placement surface 21a, and a built-in heater electrode 22b on the side away from the wafer placement surface 21a. The wafer attraction electrode 22a is made of materials including one or more of e.g., W, Mo, WC, and MoC. The wafer attraction electrode 22a is a disk-shaped or meshed monopolar electrostatic electrode. Each layer above the wafer attraction electrode 22a in the ceramic plate 21 functions as a dielectric layer. The wafer attraction electrode 22a is connected via a power terminal 54a to a wafer attraction power supply 52a serving as a DC power supply. The power terminal 54a is provided from the lower surface of the ceramic plate 21 to the wafer attraction electrode 22a through an insulation tube 55a disposed in a through hole which vertically penetrates the base member 30, the back-side plate 23 and the metal joint layer 29. The heater electrode 22b is made of materials including one or more of e.g., WC, W, MoC, and Mo. The ceramics used for the ceramic plate 21 may be added to the heater electrode 22b. The heater electrode 22b is formed of e.g., a band-shaped (flat and elongated ribbon shaped) or coil-shaped resistance heating element formed in a plane parallel to the wafer placement surface 21a. The heater electrode 22b is wired without being crossed from one to the other of a pair of ends in the resistance heating element in a one-stroke pattern over the entire ceramic plate 21. The heater electrode 22b is connected via a power terminal 54b to a heater power supply 52b serving as an AC power supply. The power terminal 54b is provided from the lower surface of the ceramic plate 21 to the heater electrode 22b through an insulation tube 55b disposed in a through hole which vertically penetrates the base member 30, the back-side plate 23 and the metal joint layer 29.

The back-side plate 23 is a disk one size larger than the ceramic plate 21, and made of a composite material (hereinafter also referred to as a metal-ceramic composite material) of metal and ceramic, ceramic or low thermal expansion metal. As the metal-ceramic composite material, a metal matrix composite material (metal matrix composite (MMC)), a ceramic matrix composite material (ceramic matrix composite (CMC)) and the like may be mentioned. As a specific example of the metal-ceramic composite material, a material containing Si, SiC and Ti, a material obtained by impregnating a SiC porous body with Al and/or Si may be mentioned. A material containing Si, SiC and Ti is referred to as SiSiCTi, a material obtained by impregnating a SiC porous body with Al is referred to as AlSiC, and a material obtained by impregnating a SiC porous body with Si is referred to as SiSiC. As a specific example of ceramic material, aluminum nitride, alumina and the like may be mentioned. The ceramic material may be, for example, the same type as the ceramic plate 21, or the same type as and lower in purity than the ceramic plate 21. As a specific example of low thermal expansion metal material, Mo and the like may be mentioned. The absolute value of the difference in the coefficients of linear thermal expansion of the material used for the back-side plate 23 and the ceramic material used for the ceramic plate 21 at 40 to 400°C is preferably lower than or equal to 1.5×10⁻⁶/K, more preferably lower than or equal to 1.0×10⁻⁶/K, and further preferably lower than or equal to 0.5×10⁻⁶/K. From the viewpoint of strength and stiffness, the thickness of the back-side plate 23 may be, for example, greater than or equal to 5 mm. From the viewpoint of reducing the heat transfer distance between the lower surface of the ceramic plate 21 and the upper surface of the base member 30, the thickness of the back-side plate 23 may be less than or equal to 25 mm.

The disposition space 24 is a space provided in the back-side plate 23, and when the joint body 20 is fastened to the base member 30, the nut 40 is disposed in the space. A plurality of (herein, six) disposition spaces 24 are provided at regular intervals in the circumferential direction of the back-side plate 23. Each disposition space 24 is provided, for example, in the area (for example, the area within a diameter of 150 mm) within half the diameter of the ceramic plate 21 from the axis of the back-side plate 23. Each disposition space 24 is formed by covering, with the ceramic plate 21, an upper opening of a bottomed hole 24a provided in the upper surface of the back-side plate 23. The bottom of the disposition space 24 is one level below the bottom of the movement lane 26. The disposition space 24 is formed in an oval shape with a width in the narrow width direction greater than the opposite side distance (width across flats) of the nut 40 and less than the width across corners of the nut 40. The rotation of the nut 40 about its axis is to be regulated by the sidewall of the disposition space 24. The height (the length from the lower surface of the ceramic plate 21 to the bottom of the disposition space 24) of the disposition space 24 should be greater than the thickness of the nut 40, and may be 1.05 times or more of the thickness of the nut 40 in consideration of the protrusion of the shaft of the bolt 50. Also, from the viewpoint of reducing the thickness of the back-side plate 23, the height of the disposition space 24 may be 3 times or less of the thickness of the nut 40. From the viewpoint of strength and stiffness, the thickness of the bottom of the disposition space 24 may be, for example, greater than or equal to 3 mm. From the viewpoint of reducing the thickness of the back-side plate, the thickness of the bottom of the disposition space 24 may be, for example, less than or equal to 20 mm. The bottom of the disposition space 24 is provided with a through hole 25 which allows the lower surface of the back-side plate 23 and the disposition space 24 to communicate with each other. The through hole 25 is formed to allow the shaft of the bolt 50 to be inserted, thus the bolt 50 can be inserted from the lower surface of the back-side plate 23 into the through hole 25, and screwed into the nut 40. The through hole 25 is formed to be thinner in width (or smaller in diameter) than the opposite side distance of the nut 40 to prevent the nut 40 from falling off.

The movement lane 26 is used for insertion and removal of the nut 40, and formed to start from a port 27 open in the lower surface of the back-side plate 23 and reach the disposition space 24 which is different from the port 27 in position in a plan view. The movement lane 26 is tunnel-shaped by covering, with the ceramic plate 21, an upper opening of a bottomed groove 26a provided in the upper surface of the back-side plate 23. The movement lane 26 is radially formed horizontally (in-plane direction of the back-side plate) to a plurality of (herein, six) disposition spaces 24 around an approximately circular one port 27 open in the central part of the lower surface of the back-side plate 23. The port 27 vertically penetrates the back-side plate 23. The movement lane 26 is formed with a width greater than the opposite side distance of the nut 40 and less than the width across corners of the nut 40. The rotation of the nut 40 about its axis is to be regulated by the sidewall of the movement lane 26. The height (the length from the lower surface of the ceramic plate 21 to the bottom of the movement lane 26) of the movement lane 26 excluding the port 27 should be greater than the thickness of the nut 40, and may be 1.05 times or more of the thickness of the nut 40. From the viewpoint of reducing the thickness of the back-side plate 23, the height of the movement lane 26 may be 3 times or less of the thickness of the nut 40. From the viewpoint of strength and stiffness, the thickness of the bottom of the movement lane 26 may be, for example, greater than or equal to 3 mm. From the viewpoint of reducing the thickness of the back-side plate 23, the thickness of the bottom of the movement lane 26 may be, for example, less than or equal to 10 mm. The bottom of the movement lane 26 is provided with a vertically penetrating slit 28 along the movement lane 26. The slit 28 is formed to have a width which allows insertion of the shaft of the bolt 50 so that the nut 40 can be moved along the movement lane 26 using the bolt 50. The slit 28 is formed to be thinner in width than the opposite side distance of the nut 40 to prevent the nut 40 from falling off. The inner space of the movement lane 26 and each disposition space 24 are combined into one. The slit 28 provided at the bottom of the movement lane 26 and the through hole 25 provided at the bottom of the disposition space 24 are combined into one.

The metal joint layer 29 joins the lower surface of the ceramic plate 21 and the upper surface of the back-side plate 23 together. The metal joint layer 29 has a through hole 29b with the same planar shape as that of the disposition space 24 and the movement lane 26 (including the port 27), and the metal joint layer 29 is not disposed over the disposition space 24 and the movement lane 26. The metal joint layer 29 may be made of e.g., solder or metal brazing material. The metal joint layer 29 is formed, for example, by TCB (Thermal compression bonding). The TCB is a publicly known method by which a metal joint material is inserted between two members to be joined, and the two members are pressurized and joined with the two members heated at a temperature lower than or equal to the solidus temperature of the metal joint material.

The base member 30 is a disk member made of metal, represented by aluminum, aluminum alloy, or stainless steel (SUS material) and the like. The outer diameter of the base member 30 is the same as the outer diameter of the back-side plate 23. A refrigerant flow path 35 is provided inside the base member 30. The refrigerant flow path 35 is provided in a swirl shape from an inlet 35a to an outlet 35b in a one-stroke pattern to cover the entire area where the ceramic plate 21 is disposed. The inlet 35a and the outlet 35b of the refrigerant flow path 35 penetrate the lower surface of the base member 30 and the bottom surface of the refrigerant flow path 35. The inlet 35a and the outlet 35b of the refrigerant flow path 35 are connected to a refrigerant cooling apparatus which is not illustrated, and the refrigerant ejected from the outlet 35b is temperature-adjusted by the refrigerant cooling apparatus, then returned to the inlet 35a again and supplied into the refrigerant flow path 35. The refrigerant which flows through the refrigerant flow path 35 is preferably liquid, and preferably has an electrical insulating property. As the liquid having an electrical insulating property, e.g., fluorine-based inert liquid may be mentioned. The base member 30 is connected via a power terminal 64 to an RF power supply 62. Thus, the base member 30 also functions as a radio frequency (RF) electrode for plasma generation. The base member 30 has a plurality of through holes 36. The through holes 36 are provided at positions opposed to the disposition spaces 24, and vertically penetrate the base member 30. Each through hole 36 has a counterbore on a lower side, and the head of the bolt 50 is stored in the counterbore.

A sealing member 70 is disposed between the joint body 20 and the base member 30. Specifically, an outer sealing member 70a is disposed slightly inward and along the outer circumferential edge, and an inner sealing member 70b is disposed inward of the outer sealing member 70a so as to surround the periphery of terminal holes 30b, 30c which vertically penetrate the base member 30. Thus, a gap (including each disposition space 24, the through hole 25, the movement lane 26, the port 27 and the slit 28) is formed between the joint body 20 and the base member 30, and a gas such as He gas is filled in a portion of the gap, the portion being inward of the outer sealing member 70a and outward of the inner sealing member 70b. A sealing member 71 is disposed between the head of the bolt 50 and the bottom of the counterbore of the through hole 36. The sealing members 70, 71 are elastically deformable annular members, and pressed vertically, thereby preventing the gas filled between the joint body 20 and the base member 30 from leaking to the outside. As the sealing members 70, 71, an o-ring and packing may be used. The sealing members 70, 71 may be made of an insulating material, or made of a conductive material. The sealing members 70, 71 may be made of resin or made of rubber, or made of metal.

The nut 40 is a hexagon nut made of metal such as stainless steel. The nut 40 is inserted from the port 27 into the inside of the back-side plate 23, and is laterally moved along the movement lane 26, then disposed in the disposition space 24. The nominal diameter of the nut 40 may be greater than or equal to e.g., 3 mm and less than or equal to 10 mm.

The bolt 50 is a hexagon bolt made of metal such as stainless steel. The bolt 50 is inserted into the through hole 36 from the lower surface of the base member 30, and screwed into the nut 40 disposed in the disposition space 24 of the back-side plate 23. The head of the bolt 50 is stored in the counterbore to prevent the head from projecting downward from the lower surface of the base member 30. The bolt 50 is screwed into the nut 40, thus the joint body 20 and the base member 30 are fastened with the sealing member 70 interposed therebetween. Thus, the sealing member 70 is compressed vertically. The nominal diameter of the bolt 50 may be greater than or equal to e.g., 3 mm and less than or equal to 10 mm.

The joint body 20 and the base member 30 are fastened by the nut 40 and the bolt 50 in the inner circumferential portion where the ceramic plate 21 is disposed, and further fastened using the bolt 75 in the outer circumferential portion where the back-side plate 23 protrudes from the ceramic plate 21. The bolt 75 is a hexagon bolt made of metal such as stainless steel. The bolt 75 is inserted from the upper surface of the back-side plate 23 into a through hole 23d provided in the outer circumferential portion of the back-side plate 23, and is screwed into a threaded hole 30d formed in the upper surface of the base member 30. The head of the bolt 75 is stored in a counterbore provided on an upper side of the through hole 23d to prevent the head from projecting upward from the upper surface of the back-side plate 23.

An annular heat insulation member 76 is disposed in the periphery of the bolt 50 and the bolt 75. Specifically, for example, the heat insulation member 76 is disposed in the periphery of part of the shaft of the bolt 50, the part disposed in the gap between the joint body 20 and the base member 30. For example, the heat insulation member 76 is disposed in the periphery of part of the shaft of the bolt 75, the part disposed in the gap between the joint body 20 and the base member 30, or in the periphery (between the bottom of the counterbore and the head of the bolt 75) of part of the shaft of the bolt 75, the part disposed in the counterbore of the through hole 23d. As the material for the heat insulation member 76, pentamethylene diisocyanate (PDI, PDI a registered trademark), zirconia and the like may be mentioned.

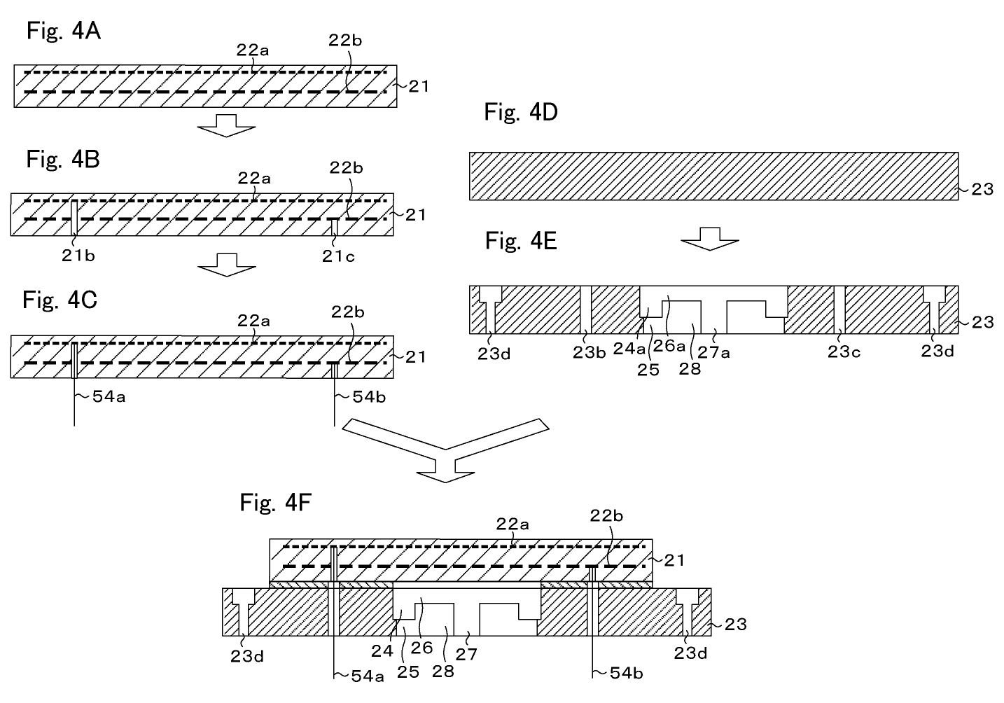

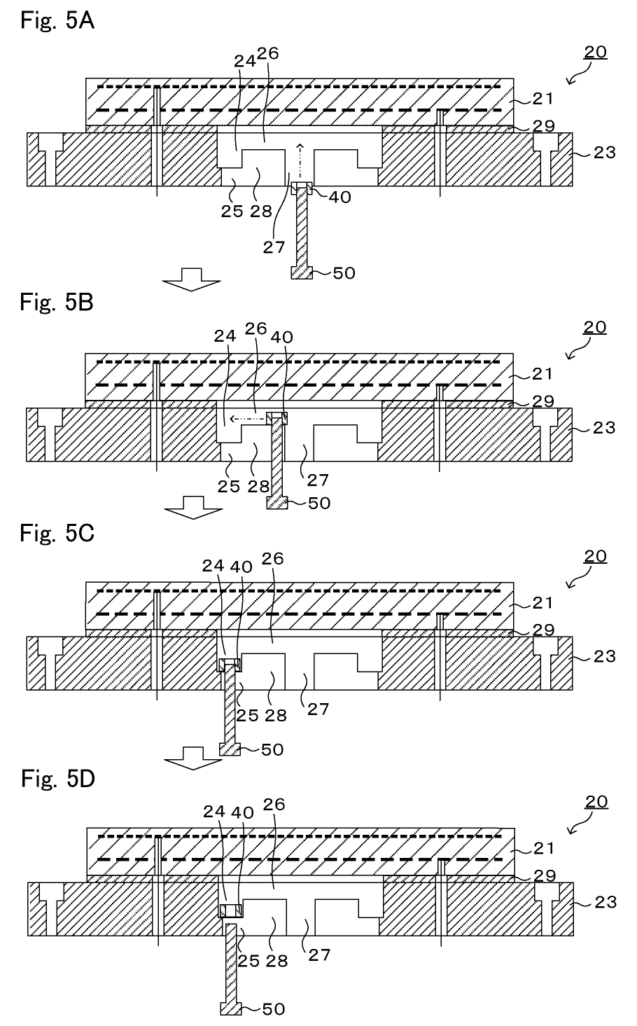

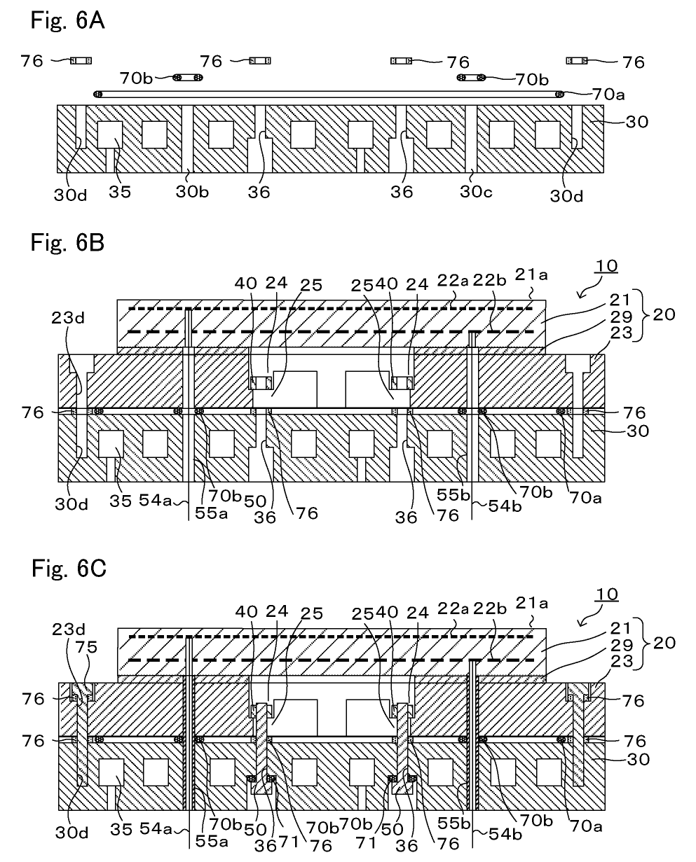

Next, a manufacturing example of the wafer placement table 10 will be described with reference to FIGS. 4 to 6. FIGS. 4 to 6 are manufacturing process diagrams of the wafer placement table 10, FIGS. 4A to 4F illustrate manufacturing processes of the joint body 20, FIGS. 5A to 5D illustrate disposition processes of the nut 40, and FIGS. 6A to 6C illustrate assembly processes of the wafer placement table 10.

The joint body 20 is produced, for example, as follows. First, the ceramic plate 21 is produced by hot-press firing a molded body of ceramic powder (FIG. 4A). The wafer attraction electrode 22a and the heater electrode 22b are embedded in the ceramic plate 21. Next, a hole 21b is opened from the lower surface of the ceramic plate 21 to the wafer attraction electrode 22a, and a hole 21c is opened from the lower surface of the ceramic plate 21 to the heater electrode 22b (FIG. 4B). The power terminal 54a is inserted into the hole 21b to join the power terminal 54a and the wafer attraction electrode 22a together, and the power terminal 54b is inserted into the hole 21c to join the power terminal 54b and the heater electrode 22b together (FIG. 4C).

Concurrently with this, the disk-shaped back-side plate 23 is produced (FIG. 4D), and vertically penetrating through holes 23b to 23d are formed in the back-side plate 23, and the bottomed hole 24a open in the upper surface of the back-side plate 23, the through hole 25 vertically penetrating the bottom of the bottomed hole 24a, the bottomed groove 26a open in the upper surface of the back-side plate 23, the slit 28 vertically penetrating the bottom of the bottomed groove 26a and a through hole 27a vertically penetrating the back-side plate 23 are formed (FIG. 4E). When the ceramic plate 21 is made of alumina, the back-side plate 23 is preferably made of SiSiCTi, or made of AlSiC. This is because the back-side plate 23 made of SiSiCTi or AlSiC has roughly the same coefficient of thermal expansion as that of alumina. The back-side plate 23 made of SiSiCTi can be produced, for example, as follows. First, silicon carbide, metal Si and metal Ti are mixed to produce a powder mixture. Next, a disk-shaped molded body is produced by applying uniaxial pressing to the obtained powder mixture, and hot press sintering is performed on the molded body in an inert atmosphere, thus the back-side plate 23 made of SiSiCTi is obtained. When the ceramic plate 21 is made of aluminum nitride, it is desirable that the back-side plate 23 be made of the same material (aluminum nitride) or made of molybdenum. This is because the back-side plate 23 made of the same material or molybdenum has roughly the same or completely the same coefficient of thermal expansion as that of the ceramic plate 21.

Next, a metal joint material is placed on the upper surface of the back-side plate 23. The metal joint material is provided with a through hole communicating with the through hole 23b of the back-side plate 23, and a through hole communicating with the bottomed hole 24a, the bottomed groove 26a, and the through hole 27a of the back-side plate 23. The power terminals 54a, 54b of the ceramic plate 21 are inserted into the through holes 23b, 23c of the back-side plate 23, and the ceramic plate 21 is placed on the metal joint material. Consequently, a stacked structure is obtained in which the back-side plate 23, the metal joint material and the ceramic plate 21 are stacked in this order. The stacked structure is pressurized while being heated (TCB), thus the joint body 20 is obtained (FIG. 4F). The joint body 20 is such that the ceramic plate 21 is joined to the upper surface of the back-side plate 23 with the metal joint layer 29 interposed therebetween. Due to the joining, the bottomed hole 24a is covered by the ceramic plate 21, and the disposition space 24 is formed. Also, due to the joining, the bottomed groove 26a and the through hole 27a are covered by the ceramic plate 21, and the tunnel-shaped movement lane 26 (having the port 27) is formed.

TCB is performed, for example, as follows. Specifically, the stacked structure is pressurized and joined at a temperature (for example, higher than or equal to the solidus temperature minus 20°C and lower than or equal to the solidus temperature) lower than or equal to the solidus temperature of the metal joint material, and subsequently, the temperature is returned to the room temperature. Thus, the metal joint material turns to a metal joint layer (or a conductive joint layer). As the metal joint material in this case, Al-Mg based joint material and Al-Si-Mg based joint material may be used. For example, when TCB is performed using Al-Si-Mg based joint material, the stacked structure is pressurized with heated in a vacuum atmosphere. It is preferable that a metal joint material with a thickness of about 100 μm be used.

The nut 40 is disposed in the disposition space 24 of the obtained joint body 20, for example, as follows. First, the nut 40 is screwed to the distal end of the shaft of the bolt 50, the bolt 50 is held, and the nut 40 is inserted into the port 27 from the lower surface of the back-side plate 23 (FIG. 5A). When the lower surface of the nut 40 exceeds the height of the bottom of the movement lane 26, the bolt 50 is laterally moved along the slit 28, thus the nut 40 is laterally moved along the movement lane 26 (FIG. 5B). When the nut 40 reaches the disposition space 24, the nut 40 is lowered to the bottom of the disposition space 24, which is further lower than the bottom of the movement lane 26 (FIG. 5C). The bolt 50 used for the movement is then rotated about the axis and removed from the nut 40, thus the nut 40 is disposed in the disposition space 24 (FIG. 5D). At this point, the width of the disposition space 24 in the narrow width direction is smaller than the width across corners of the nut 40, and the rotation of the nut 40 about its axis is regulated, thus the bolt 50 can be easily removed only by rotating the bolt 50.

The wafer placement table 10 is produced by fastening, with the bolt 50, the base member 30 and the joint body 20 produced as described above to include the nut 40 internally. The base member 30 is prepared which is made of e.g., metal such as aluminum, aluminum alloy, and stainless steel, and includes: the refrigerant flow path 35 internally; the terminal holes 30b, 30c vertically penetrating the base member; the threaded hole 30d open in the upper surface of the base member 30; and the through hole 36 vertically penetrating the base member. The annular outer sealing member 70a with a diameter slightly smaller than the outer circumference of the back-side plate 23, and the annular inner sealing member 70b with a diameter slightly larger than the openings of the terminal holes 30b, 30c open in the upper surface of the base member 30 are each disposed on the upper surface of the base member 30. On the upper surface of the base member 30, in the periphery of the threaded hole 30d and the through hole 36, the heat insulation member 76 with a diameter slightly larger than the opening of each hole is disposed (FIG. 6A). Next, while the power terminal 54a of the joint body 20 is being inserted into the terminal hole 30b, and the power terminal 54b of the joint body 20 is being inserted into the terminal hole 30c, the joint body 20 is placed on the sealing members 70a, 70b and the heat insulation member 76 which are disposed on the upper surface of the base member 30 (FIG. 6B). Next, the annular sealing member 71 is passed through the shaft of the bolt 50, and for each through hole 36, the bolt 50 is inserted from the lower surface of the base member 30, and screwed into the nut 40 disposed in the disposition space 24 of the back-side plate 23. At this point, the width of the disposition space 24 in the narrow width direction is smaller than the width across corners of the nut 40, and the rotation of the nut 40 about its axis is regulated, thus the bolt 50 can be easily screwed into the nut 40. Also, the annular heat insulation member 76 is passed through the shaft of the bolt 75, and for each through hole 23d, the bolt 75 is inserted from the upper surface of the back-side plate 23, and screwed into the threaded hole 30d open in the upper surface of the base member 30. In this manner, screwing the bolt 50 and the bolt 75 causes the sealing members 70, 71 to be compressed, and their sealing function is exhibited. Subsequently, the insulation tubes 55a, 55b, which allow the power terminals 54a, 54b to be inserted, are inserted through the terminal holes 30b, 30c. As described above, the wafer placement table 10 can be obtained (FIG. 6C). In the wafer placement table 10, even if a failure occurs in the nut 40, taking out the nut 40 in which a failure has occurred by a procedure reversed from the procedure of FIGS. 5A to 5D and FIGS. 6A to 6C, and disposing a new nut 40 in the disposition space 24 by the procedure of FIGS. 5A to 5D enable fastening of the joint body 20 and the base member 30 illustrated in FIGS. 6A to 6C again.

Next, an example of use of the wafer placement table 10 will be described with reference to FIG. 1. First, the wafer placement table 10 is fixed to the installation plate 96 of the chamber 94 using a bolt 80. A disk-shaped wafer W is placed on the wafer placement surface 21a of the wafer placement table 10 installed in the installation plate 96. In this state, a DC voltage of the wafer attraction power supply 52a is applied to the wafer attraction electrode 22a, causing the wafer W to be attracted to the wafer placement surface 21a. The temperature of the wafer placement surface 21a is adjusted by passing a temperature-regulated refrigerant through the refrigerant flow path 35, and/or applying an AC voltage of the heater power supply 52b to the heater electrode 22b. The inside of the chamber 94 is set to a predetermined vacuum atmosphere (or a reduced pressure atmosphere), and an RF voltage from the RF power supply 62 is applied to the base member 30 while supplying a process gas from a shower head 98. Then, plasma is generated between the wafer W and the shower head 98. By utilizing the plasma, CVD film deposition and etching are performed on the wafer W.

In the wafer placement table 10 described above, in addition to the disposition space 24 in which the nut 40 is disposed, the joint body 20 includes the movement lane 26 used for insertion and removal of the nut 40. Thus, the nut 40 can be replaced, and even if a failure occurs in the nut 40, it can be replaced with a new nut 40, enabling fastening again, and the joint body 20 is prevented from becoming unusable due to a failure of the nut 40.

Also, the bottom of the movement lane 26 is provided with the vertically penetrating slit 28 along the movement lane 26, thus the nut 40 can be easily replaced by inserting a jig or the like through the slit 28 and using the jig to move the nut 40 within the movement lane 26.

In addition, the width of the slit 28 allows insertion of the shaft of the bolt 50 to be screwed into the nut 40, thus the nut 40 can be replaced using the bolt 50 or the like used to fasten the base member 30 without specifically preparing a jig.

Furthermore, the sidewall of the disposition space 24 is configured to regulate the rotation of the nut 40 about an axis, thus fastening and removal of fastening with a rotation, such as screwing can be easily performed without performing a process such as rotation stop of the joint-body-side fastening member.

The movement lane 26 starts from one port 27 and reaches a plurality of disposition spaces 24, thus a plurality of nuts 40 can be inserted and removed from one port 27, thus each nut 40 can be easily replaced.

The back-side plate 23 is made of a composite material of metal and ceramic, made of ceramic, or made of low thermal expansion metal, and has a small difference in the coefficient of thermal expansion from the ceramic plate 21, thus warpage and delamination due to the difference in the coefficient of thermal expansion are unlikely to occur in the joint body. Thus, the back-side plate 23 can be joined to the back side of the ceramic plate 21 by metal joining. The metal joining is also suitable for joining dissimilar materials, and provides high heat resistance, thus is preferable. The metal joining is often performed at a high temperature higher than or equal to the melting point of metal, and the metal joining with the nut 40 embedded in the back-side plate 23 may be practically impossible in consideration of alteration of quality of the nut 40. It is highly significant to adopt the present invention which allows the nut 40 to be inserted into the back-side plate 23 after joining.

Furthermore, a gas is filled in the space between the back side of the joint body 20 and the upper surface of the base member 30, thus heat transfer between the joint body 20 and the base member 30 can be adjusted by the gas.

Furthermore, the heat insulation member 76 is disposed in the periphery of the bolt 50 and the bolt 75, thus heat transfer through the bolt 50 and the bolt 75 between the joint body 20 and the base member 30 is reduced, and occurrence of an extreme temperature difference is reduced between portion immediately above or its peripheral area of the bolt 50, the bolt 75 and other areas on the wafer placement surface 21a.

Note that the present invention is not limited to the above-described embodiment at all, and it is needless to say that the present invention can be carried out in various forms as long as the forms belong to the technical scope of the present invention.

For example, in the above-described embodiment, the back-side plate 23 is one size larger than the ceramic plate 21, but may have the same diameter as the ceramic plate 21. In this case, the metal joint layer 29 also preferably has the same diameter as the ceramic plate 21. The base member 30 has the same diameter as the back-side plate 23, but may be larger in diameter than the back-side plate 23.

In the above-described embodiment, the bottom of the disposition space 24 is one step lower than the bottom of the movement lane 26, but may be at the same height as the bottom of the movement lane 26, for example.

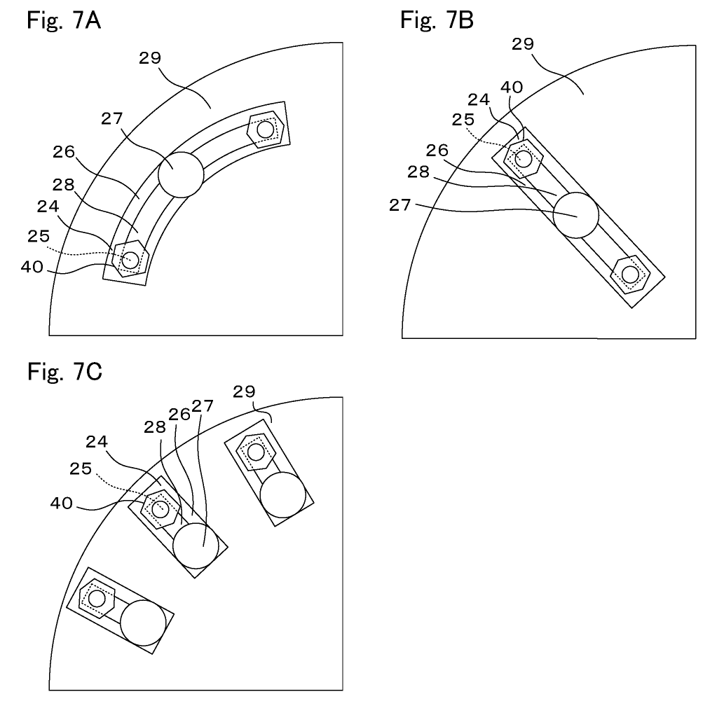

In the above-described embodiment, the movement lane 26 is radially formed to a plurality of disposition spaces 24 around one port 27, but without being limited to this, may be formed as illustrated in FIGS. 7A to 7C, for example. Note that FIGS. 7A to 7C illustrate partial enlarged views (enlarged views of quarter-circles of the area where the ceramic plate 21 is disposed) of the plan view of the wafer placement table 10 excluding the ceramic plate 21. For example, as illustrated in FIG. 7A, the movement lane 26 may be formed to reach a plurality of disposition spaces 24 around one port 27 arranged at positions with the same distance from the axis of the joint body 20 (multiple positions for disposition within the same diameter). For example, as illustrated in FIG. 7B, the movement lane 26 may be formed to reach a plurality of disposition spaces 24 arranged on a predetermined radius of the joint body 20 around one port 27 (multiple positions for disposition within the same angle). Also, for example, as illustrated in FIG. 7C, the movement lane 26 may be formed to reach one disposition space 24 from one port 27 (single position for disposition). Note that in FIGS. 7A to 7C, the same components as in the above-described embodiment are labeled with the same symbol.

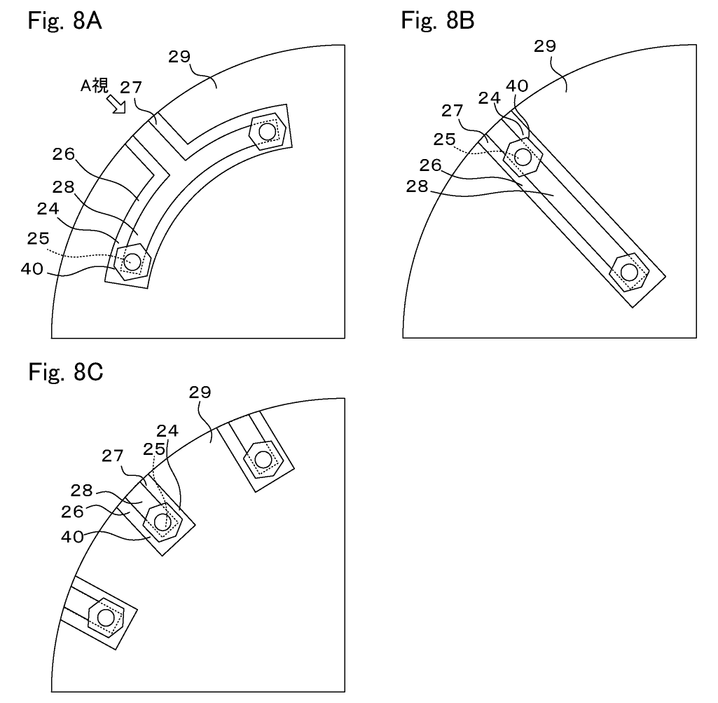

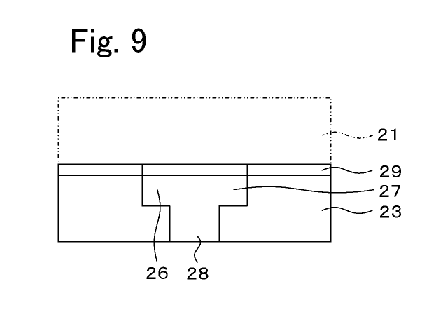

In the above-described embodiment and in another example of the movement lane 26 illustrated in FIGS. 7A to 7C, the port 27 is open in the lower surface of the back-side plate 23, but without being limited to this, may be open in the side surface of the back-side plate 23, for example, as illustrated in FIGS. 8 and 9. Note that FIGS. 8A to 8C illustrate partial enlarged views (enlarged views of quarter-circles of the area where the ceramic plate 21 is disposed) of the plan view of the wafer placement table 10 excluding the ceramic plate 21. FIG. 9 is a partially enlarged view in FIG. 8A as seen in arrow A. Note that in FIG. 9, the ceramic plate 21 not illustrated in FIGS. 8A to 8C is indicated by a two-dot chain line. When the port 27 is open in the side surface, for example, as illustrated in FIG. 8A, the movement lane 26 may be formed to reach a plurality of disposition spaces 24 which branch from one port 27 and are arranged at positions with the same distance from the axis of the joint body 20 (multiple positions for disposition within the same diameter). For example, as illustrated in FIG. 8B, the movement lane 26 may be formed to reach a plurality of disposition spaces 24 which are not branched from one port 27 and arranged on a predetermined radius of the joint body 20 (multiple positions for disposition within the same angle). Also, for example, as illustrated in FIG. 8C, the movement lane 26 may be formed to reach one disposition space 24 from one port 27 (single position for disposition). Note that when the port 27 is open in the side surface of the back-side plate 23, it is preferable that the ceramic plate 21 and the back-side plate 23 have the same diameter. In this manner, the movement lane 26 is not exposed to the upper surface of the back-side plate 23. Note that in FIGS. 8 and 9, the same components as in the above-described embodiment are labeled with the same symbol.

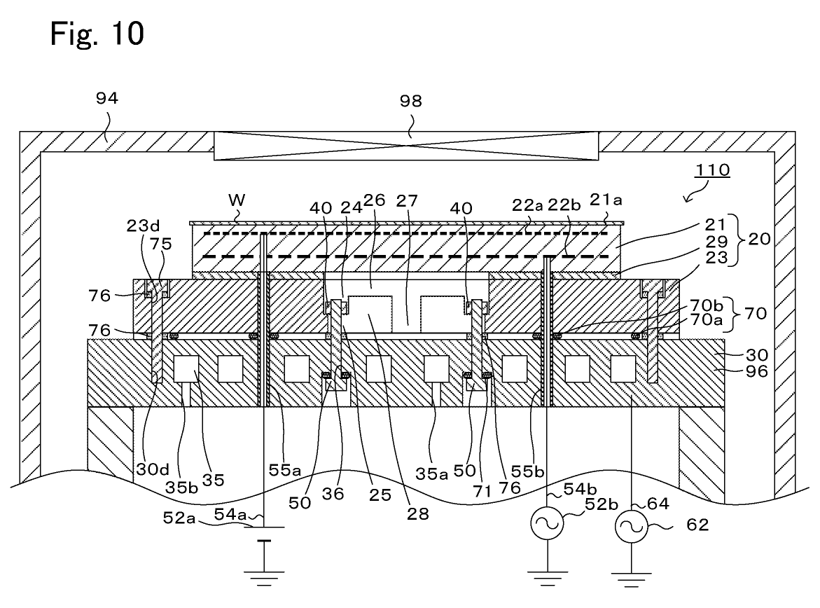

In the above-described embodiment, the wafer placement table 10 in which the joint body 20 and the base member 30 are fastened with the bolt 50 is installed in the installation plate 96 of the chamber 94, but this is not always the case. For example, as in the wafer placement table 110 illustrated in FIG. 10, the base member 30 may be used concurrently with the installation plate 96 of the chamber 94. Note that in FIG. 10, the same components as in the above-described embodiment are labeled with the same symbol.

In the above-described embodiment, the nut 40 is used as the joint-body-side fastening member, but instead of the nut 40, a bolt similar to the bolt 50 may be used. In that case, as the base-side fastening member, a nut formed similarly to the nut 40 may be used. Alternatively, as the base-side fastening member, a threaded hole provided to be open in the upper surface of the base member 30 may be used. Note that the nut 40 is a hexagon nut, but without being limited to this, may be a square nut or an octagonal nut. The same applies to the bolt 50.

In the above-described embodiment, the bottom of the movement lane 26 is provided with the slit 28, but the slit 28 may be omitted. Note that when a bolt is used as the joint-body-side fastening member, the slit 28 is not omitted.

In the above-described embodiment, the nut 40 is replaced using the bolt 50, but a jig other than the bolt may be used. In that case, the slit 28 preferably has a width which allows insertion of a jig.

In the above-described embodiment, the ceramic plate 21 and the back-side plate 23 are joined by metal joining, but may be joined by direct joining, for example. In that case, the ceramic plate 21 and the back-side plate 23 are directly joined not via the metal joint layer 29. In the case of direct joining, the back-side plate 23 is made of ceramic, preferably made of ceramic similar to the ceramic plate 21. The direct joining may be a method of joining the lower surface of the ceramic plate 21 and the upper surface of the back-side plate 23 together by direct contact with each other, but it is preferable to adopt a method of pressurizing and joining both plates with the plates in contact with each other and heated to a temperature higher than or equal to the melting point of ceramic. For direct joining, the ceramic plate 21 and the back-side plate 23 before firing may be used, but it is preferable to use the ceramic plate 21 and the back-side plate 23 after firing (preferably after hot-press). The ceramic plate 21 and the back-side plate 23 may be bonded by a resin adhesive. In the direct joining, the periphery of the boundary between the ceramic plate 21 and the back-side plate 23 may include a diffusion layer in which components of both plates are diffused.

In the above-described embodiment, the wafer attraction electrode 22a and the heater electrode 22b are embedded in the ceramic plate 21, but one of the electrodes may be omitted, and instead of or in addition to at least one of the electrodes, an RF electrode for plasma generation may be embedded in. When an RF electrode is embedded in, a radio frequency power supply is connected to the RF electrode not to the base member 30.

In the above-described embodiment, one heater electrode 22b is provided, but a plurality of heater electrodes 22b may be provided. For example, heater electrodes 22b may be provided for each zone such as an inner circumferential zone and an outer circumferential zone.

In the above-described embodiment, the refrigerant flow path 35 is provided in a swirl shape from the inlet 35a to the outlet 35b, but the shape of the refrigerant flow path 35 is not limited to a specific one. In the above-described embodiment, one refrigerant flow path 35 is provided, but a plurality of refrigerant flow paths 35 may be provided. For example, refrigerant flow paths 35 may be provided for each zone such as an inner circumferential zone and an outer circumferential zone.

In the above-described embodiment, the ceramic plate 21 is produced by hot-press firing a molded body of ceramic powder, and the molded body then may be produced by stacking multiple sheets of tape molded bodies, or may be produced by mold casting, or may be produced by pressing ceramic powder.

In the above-described embodiment, a hole penetrating the wafer placement table 10 may be provided from the lower surface of the base member 30 to the wafer placement surface 21a. As the hole, a gas supply hole for supplying heat transfer gas (such as He gas) to the back side of the wafer W, and a lift pin hole for passing a lift pin to raise or lower the wafer W with respect to the wafer placement surface 21a may be mentioned. The heat transfer gas is supplied to the space formed by the wafer W and a large number of small projections (supporting the wafer W) which are provided on the wafer placement surface 21a and not illustrated.

What is claimed is:

1. A joint body used by being fastened to a base member, the joint body comprising:
a ceramic plate that has a wafer placement surface on its upper surface, and an electrode embedded therein;
a back-side plate joined to a back side of the ceramic plate;
a disposition space in which a joint-body-side fastening member is disposed at a time of fastening, the disposition space being provided in the back-side plate and having a through hole at a bottom; and
a movement lane used for insertion and removal of the joint-body-side fastening member, the movement lane starting from a port open in a lower surface or a side surface of the back-side plate and reaching the disposition space which is different from the port in position in a plan view.

2. The joint body according to claim 1,
wherein a bottom of the movement lane is provided with a vertically penetrating slit along the movement lane.

3. The joint body according to claim 2,
wherein the joint-body-side fastening member is a nut, and the slit has a width which allows insertion of a shaft of a bolt to be screwed into the joint-body-side fastening member, or the joint-body-side fastening member is a bolt, and the slit has a width which allows insertion of the shaft of the bolt of the joint-body-side fastening member.

4. The joint body according to claim 1,
wherein a sidewall of the disposition space regulates rotation of the joint-body-side fastening member about an axis.

5. The joint body according to claim 1,
wherein the movement lane starts from the port and reaches a plurality of disposition spaces each of which is the disposition space.

6. The joint body according to claim 1,
wherein the back-side plate is made of ceramic, and joined to the back side of the ceramic plate by direct joining.

7. The joint body according to claim 1,
wherein the back-side plate is made of a composite material of metal and ceramic, made of ceramic, or made of low thermal expansion metal, and joined to the back side of the ceramic plate by metal joining.

8. A member for semiconductor manufacturing apparatus, comprising the joint body according to claim 1,
the member comprising:
the base member;
the joint-body-side fastening member; and
a base-side fastening member to be used in combination with the joint-body-side fastening member.

9. The member for semiconductor manufacturing apparatus according to claim 8,
wherein a gas is filled in space between a back side of the joint body and an upper surface of the base member.

10. The member for semiconductor manufacturing apparatus according to claim 8,
wherein a heat insulation member is disposed in a periphery of at least one of the joint-body-side fastening member or the base-side fastening member.
